(19) United States
(12) Patent Application Publication
(10) Pub. No.: US 2013/0336053 A1
(43) Pub. Date: Dec. 19, 2013

(54) Paralleled Drive Devices Per Bitline in Phase-Change Memory Array

(71) Applicant: Being Advanced Memory Corporation, (US)

(72) Inventors: Christopher Scoville, Burlington, VT (US); Wolfgang Hokenmaier, Burlington, VT (US)

(73) Assignee: Being Advanced Memory Corporation, Essex Junction, VT (US)

(21) Appl. No.: 13/869,827

(22) Filed: Apr. 24, 2013

Related U.S. Application Data
(60) Provisional application No. 61/637,496, filed on Apr. 24, 2012.
(60) Provisional application No. 61/784,602, filed on Mar. 14, 2013.
(60) Provisional application No. 61/637,513, filed on Apr. 24, 2012.
(60) Provisional application No. 61/784,579, filed on Mar. 14, 2013.

(51) Int. Cl. G11C 13/00

(52) U.S. Cl. CPC G11C 13/0004
USPC 365/163; 365/148

(57) ABSTRACT

Methods and systems for phase change memory having high RESET currents. In some sample embodiments, PCM elements share access devices in parallel between bit lines, permitting higher RESET currents to be shared between several access devices without overdriving. Lower individual current densities permit smaller access devices and smaller memories having greater reliability and longer retention. In some sample embodiments, hybrid arrays connect bit lines on only a few word lines, using the shared bits e.g. only for critical information. In some sample embodiments, several PCM elements share a single larger access device which can pass higher currents while still reducing the total memory size.

### CROSS-REFERENCE

Priority is claimed from 61/637,496 filed Apr. 24, 2012, which is hereby incorporated by reference.

Priority is claimed from 61/637,513 filed Apr. 24, 2012, which is hereby incorporated by reference.

Priority is claimed from 61/784,602 filed Mar. 14, 2013, which is hereby incorporated by reference.

Priority is claimed from 61/784,579 filed Mar. 14, 2013, which is hereby incorporated by reference.

### BACKGROUND

The present application relates to phase-change memory systems, and more particularly to phase-change memory systems having high-current RESET operations.

Note that the points discussed below may reflect the hindsight gained from the disclosed inventions, and are not necessarily admitted to be prior art.

Phase change memory (“PCM”) is a relatively new nonvolatile memory technology, which is very different from any other kind of nonvolatile memory. First, the fundamental principles of operation, at the smallest scale, are different: no other kind of solid-state memory uses a reversible PHYSICAL change to store data. Second, in order to achieve that permanent physical change, an array of PCM cells has to allow read, set, and reset operations which are all very different from each other. The electrical requirements of the read, set, and reset operations make the peripheral circuit operations of a PCM very different from those of other nonvolatile memories. Obviously some functions, such address decoding and bus interface, can be the same; but the closest-in parts of the periphery, which perform set, reset, and read operations on an array or subarray, must satisfy some unique requirements.

The physical state of a PCM cell's memory material is detected as resistance. For each selected cell, its bitline is set to a known voltage, and the cell's access transistor is turned on (by the appropriate wordline). If the cell is in its low-resistance state, it will sink a significant current from the bit line; if it is not, it will not.

Set and Reset operations are more complicated. Both involve heat. As discussed below, a “set” operation induces the memory material to recrystallize into its low-resistance (polycrystalline) state; a “reset” operation anneals the memory material into its high-resistance (amorphous) state.

Write operations (Set and Reset) normally have more time budget than read operations. In read mode a commercial PCM memory should be competitive with the access speed (and latency if possible) of a standard DRAM. If this degree of read speed can be achieved, PCM becomes very attractive for many applications.

The phase change material is typically a chalcogenide glass, using amorphous and crystalline (or polycrystalline) phase states to represent bit states.

A complete PCM cell can include, for example: a top electrode (connected to the bit line), a phase change material (e.g. a chalcogenide glass), a conductive pillar which reaches down from the bottom of the phase change material, an access transistor (gated by a word line), and a bottom connection to ground. The phase change material can extend over multiple cells (or over the whole array), but the access transistors are laterally isolated from each other by a dielectric.

FIG. 2A shows an example of a PCM element 2010. A top electrode 2020 overlies a phase change material 2030, e.g. a chalcogenide glass. Note that material 2030 also includes a mushroom-shaped annealed zone (portion) 2070 within it. (The annealed zone 2070 may or may not be present, depending on what data has been stored in this particular location.) The annealed zone 2070, if present, has a much higher resistivity than the other (crystalline or polycrystalline) parts of the material 2030.

A conductive pillar 2050 connects the material 2030 to a bottom electrode 2040. In this example, no selection device is shown; in practice, an access transistor would normally be connected in series with the phase change material. The pillar 2050 is embedded in an insulator layer 2060.

When voltage is applied between the top 2020 and bottom 2040 electrodes, the voltage drop will appear across the high-resistivity zone 2070 (if present). If sufficient voltage is applied, breakdown will occur across the high-resistivity zone. In this state the material will become very conductive, with large populations of mobile carriers. The material will therefore pass current, and current crowding can occur near the top of the pillar 2050. The voltage which initiates this conduction is referred to as the “snapback” voltage, and FIG. 2C shows why.

FIG. 2C shows an example of instantaneous I-V curves for a device like that of FIG. 2A, in two different states. Three zones of operation are marked.

In the zone 2200 marked “READ,” the device will act either as a resistor or as an open (perhaps with some leakage). A small applied voltage will result in a state-dependent diffrence in current, which can be detected.

However, the curve with open circles, corresponding to the amorphous state of the device, shows some more complex behaviors. The two curves show behaviors under conditions of higher voltage and higher current.

If the voltage reaches the threshold voltage Vₜₕ, current increases dramatically without any increase in voltage. (This occurs when breakdown occurs, so the phase-change material suddenly has a large population of mobile carriers.) Further increases in applied voltage above Vₜₕ result in further increases in current; note that this upper branch of the curve with hollow circles shows a lower resistance than the curve with solid squares.

If the applied voltage is stepped up to reach the zone 2150, the behavior of the cell is now independent of its previous state.

When relatively large currents are applied, localized heating will occur at the top of the pillar 2050, due to the relatively high current density. Current densities with typical dimensions can be in the range of tens of millions of Amperes per square cm. This is enough to produce significant localized heating within the phase-change material.

This localized heating is used to change the state of the phase-change material, as shown in FIG. 2B. If maximum current is applied in a very brief pulse 2100 and then abruptly stopped, the material will tend to quench into an amorphous high-resistivity condition; if the phase-change material is cooled more gradually and/or not heated as high as zone 2150, the material can recrystallize into a low-resistivity condition. Conversion to the high-resistance state is normally referred to as “Reset”, and conversion to the low-resistance state is normally referred to as “Set” (operation 2080). Note that, in this example, the Set pulse has a tail where current is reduced fairly gradually, but the Reset pulse does not. The duration of the Set pulse is also much longer than that of the Reset pulse, e.g. tens of microseconds versus hundreds of nanoseconds.

FIG. 2D shows an example of temperature versus resistivity for various PCM materials. It can be seen that each curve has a notable resistivity drop 2210 at some particular temperature. These resistivity drops correspond to phase change to a crystalline (or polysilicon) state. If the material is cooled gradually, it remains in the low resistivity state after cooling.

In a single-bit PCM, as described above, only two phases are distinguished: either the cell does or does not have a significant high-resistivity “mushroom cap” 2070. However, it is also possible to distinguish between different states of the mushroom cap 2070, and thereby store more than one bit per cell.

FIG. 2E shows an equivalent circuit for an “upside down” PCM cell 2010. In this example the pass transistor 2240 is gated by Wordline 2230, and is connected between the phase-change material 2250 and the bitline 2220. (Instead, it is somewhat preferable to connect this transistor between ground and the phase-change material.

FIG. 2F shows another example of a PCM cell 2010. A bitline 2220 is connected to the top electrode 2020 of the phase-change material 2250, and transistor 2240 which is connected to the bottom electrode 2030 of the PCM element. (The wordline 2230 which gates the vertical transistor 2240 is not shown in this drawing.) Lines 2232, which are shown as separate (and would be in a diode array), may instead be a continuous sheet, and provide the ground connection.

FIG. 2G shows an example of resistance (R) over time (t) for a single PCM cell following a single PCM write event at time t=0. The resistance curve 2400 for a cell which has been reset (i.e. which is in its high-resistance state) may rise at first, but then drifts significantly lower. The resistance curve 2410 for a cell in the Set state is much flatter. The sense margin 2420, i.e., the difference between set and reset resistances, also decreases over time. Larger sense margins generally result in more reliable reads, and a sense margin which is too small may not permit reliable reading at all. 2G represents the approximate behavior of one known PCM material; other PCM material compositions may behave differently. For example, other PCM material compositions may display variation of the set resistance over time.

The downwards drift of reset resistance may be due to, for example, shrinking size of the amorphous zone of the phase-change material, due to crystal growth; and, in some cells, spontaneous nucleation steepening the drift curve (possibly only slightly) due to introducing further conductive elements into the mushroom-shaped programmable region.

FIG. 2H shows an example of a processing system 2300. Typically, a processing system 2300 will incorporate at least some of interconnected power supplies 2310, processor units 2320 performing processing functions, memory units 2330 supplying stored data and instructions, and I/O units 2340 controlling communications internally and with external devices 2350.

FIG. 2I shows an example of a PCM single ended sensing memory. Two different PCM cells 2400 on different ends of a sense amplifier can be selected separately. Selected elements 2410 are separately sensed by a single-ended sense amplifier 2420.

FIG. 2J shows an example of a known PCM single ended sense amplifier 2500. Generally, in a single ended sense amplifier, a cell read output conducted by a selected bitline BLB is compared against a reference current to provide a digital output OUT. When the PRECHARGE signal turns on transistor 2530, voltage V04 (e.g., 400 mV) precharges the bitline BLB. After precharge ends, the READ signal turns on transistor 2550. Transistor 2550 is connected, through source follower 2560 and load 2580, to provide a voltage which comparator 2600 compares to Voltage_REF, to thereby generate the digital output OUT.

A variety of nonvolatile memory technologies have been proposed over recent decades, and many of them have required some engineering to provide reference values for sensing. However, the requirements and constraints of phase-change memory are fundamentally different from those of any other kind of nonvolatile memory. Many memory technologies (such as EEPROM, EPROM, MNOS, and flash) test the threshold voltage of the transistor in a selected cell, so referencing must allow for the transistor's behavior. By contrast, phase-change memory simply senses the resistance of the selected cell. This avoids the complexities of providing a reference which will distinguish two (or more) possibilities for an active device's state, but does require detecting a resistance value, and tracking external variations (e.g. temperature and supply voltage) which may affect the instantaneous value of that resistance.

The possibility of storing more than one bit of data in a single phase-change material has also been suggested. Phase-change memories implementing such architectures are referred to here as “multibit” PCMs. If the “Set” and/or “Reset” operations can be controlled to produce multiple electrically distinguishable states, then more than one bit of information can be stored in each phase-change material location. It is known that the current over time profile of the Set operation can be controlled to produce electrically distinguishable results, though this can be due to more than one effect. In the simplest implementation, shorter anneals—too short to produce full annealing of the amorphous layer—can be used to produce one or more intermediate states. In some materials, different crystalline phases can also be produced by appropriate selection of the current over time profile. However, what is important for the present application is merely that electrically distinguishable states can be produced.

For example, if the complete layer of phase-change material can have four possible I/V characteristics, two bits of information can be stored in each cell—IF the read cycle can accurately distinguish among the four different states.

(The I/V characteristics of the cells which are not in the fully Set state are typically nonlinear, so it is more accurate to distinguish the states in terms of current flow at a given voltage; resistance is often used as a shorthand term, but implies a linearity which may not be present.)

In order to make use of the possible multibit cell structures, it is necessary to reliably distinguish among the possible states. To make this distinction reliably, there must be some margin of safety, despite the change in characteristics which may occur due to history, manufacturing tolerances, and environmental factors. Thus the read architecture of multibit PCMs is a far more difficult challenge it is for PCMs with single-bit cells.

### SUMMARY

The present application discloses new approaches to phase-change memory systems having high-current RESET operations.

The present inventor has realized that large currents are preferably used for high-resistance RESET operations. Larger RESET currents can result in higher resistances in the RESET state. The higher RESET resistance can in turn provide faster read times, more accurate read results, and longer data retention times. However, these large currents often cannot be passed by a single access device.

The lower bound on PCM device size is generally set by the size of the access devices. As the access device decreases in size, the current that it can pass also decreases. Since each PCM element has its own access device, this means that the minimum size of the PCM device is constrained by the maximum current to be passed through each access device.

The present inventor has realized, however, that the minimum size of the PCM device can be decreased if several PCM elements on a single word line share common access devices. This can be, e.g., by connecting PCM elements from different bit lines to respective access devices in parallel, so that the current density in each access device is decreased. This can also be, e.g., by connecting multiple PCM elements in parallel to share a single larger access device, in which case fewer access devices are needed.

The disclosed innovations, in various embodiments, provide one or more of at least the following advantages. However, not all of these advantages result from every one of the innovations disclosed, and this list of advantages does not limit the various claimed inventions.
Increased current capacity
Decreased current density through access devices
Decreased cell size
Increased reliability
Similar current from lower voltage
No overdriving of access devices

### BRIEF DESCRIPTION OF THE DRAWINGS

The disclosed inventions will be described with reference to the accompanying drawings, which show important sample embodiments and which are incorporated in the specification hereof by reference, wherein:

FIG. 1 shows one sample embodiment of the present inventions.

FIG. 2A shows an example of a PCM element.

FIG. 2B shows an example of PCM bit line signals.

FIG. 2C shows an example of voltage versus current in a PCM material.

FIG. 2D shows an example of temperature versus resistance in a PCM material.

FIG. 2E shows an example of a PCM cell.

FIG. 2F shows an example of a PCM cell.

FIG. 2G shows an example of resistance over time for a PCM cell.

FIG. 2H shows an example of a processing system.

FIG. 2I shows an example of a PCM single ended sensing memory.

FIG. 2J shows an example of a known PCM single ended sense amplifier.

FIG. 3 shows one sample embodiment of the present inventions.

FIG. 4 shows a presently less-favored sample embodiment of the present inventions.

FIG. 5 shows another presently less-favored sample embodiment of the present inventions.

FIG. 6 shows yet another sample embodiment of the present inventions.

FIG. 7 shows a sample embodiment of a hybrid array according to the present inventions.

FIG. 8 shows another sample embodiment of the present inventions.

FIG. 9 shows another sample embodiment of the present inventions.

FIG. 10 shows another sample embodiment of the present inventions.

FIG. 11 shows another sample embodiment of the present inventions.

### DETAILED DESCRIPTION OF SAMPLE EMBODIMENTS

The numerous innovative teachings of the present application will be described with particular reference to presently preferred embodiments (by way of example, and not of limitation). The present application describes several inventions, and none of the statements below should be taken as limiting the claims generally.

One advantage of the present inventions is that the voltage on the word line can be held at a constant throughout operation (though not required). Conventionally, the word line voltage during RESET operations can easily be twice the word line voltage of a SET operation. When several access devices are shared as taught by the present inventions, the resultant RESET current can be split between the shared access devices. This permits the use of greater RESET currents without overdriving the access devices.

In some presently-preferred sample embodiments, only some word lines have shared bit lines. This can be particularly advantageous when a portion of the stored data needs to reliably remain for a long time while the remainder of the data is not as critical.

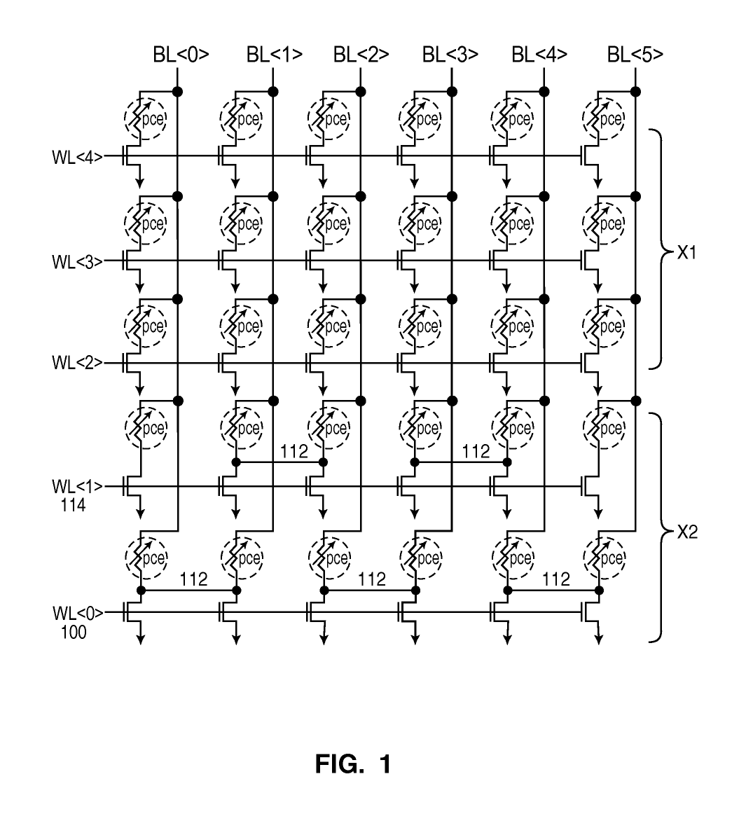

FIG. 1 shows one sample embodiment of a hybrid phase change memory array, in which only some word lines have shared bit line connections. Here, only word lines 100 and 114 have bit line sharing, and groups of two phase change elements are connected in parallel. Connections 112 are alternated between word lines, so that every phase change element on word lines 100 and 114 is connected to exactly one other phase change element on the same word line (with the possible exception of the elements at either end of word line 114).

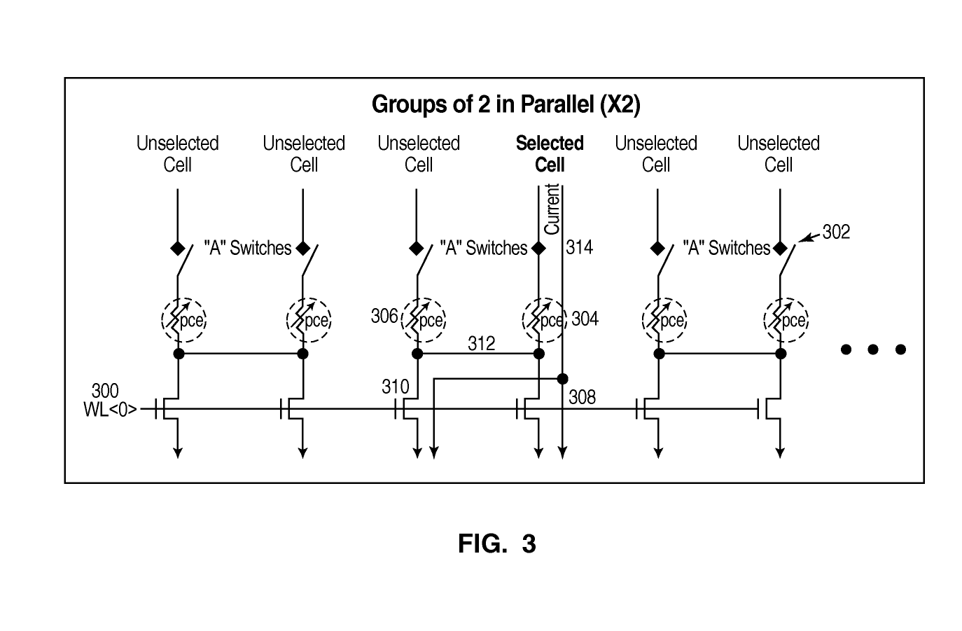

The sample embodiment of FIG. 3 shows a simplified schematic in which only one word line 300 is present. Switches 302 represent the selection state of the bit line. When switch 302 is closed, the bit line is selected, and when switch 302 is open, the bit line is unselected. Switches 302 are generally representative of the selection state rather than physical switches, but can optionally be physical switches. Connection 312 runs from the bottom electrode of PCM element 304 or the top electrode of access device 308 to the bottom electrode of PCM element 306 or the top electrode of access device 310. (Note that “top” and “bottom” here are used in relation to the arrangement in the diagram of FIG. 3, and do not necessarily speak to the physical arrangement of elements.) When switch 314 is closed (i.e. the bit line in question is selected) and word line 300 is selected, current flows through PCM element 304. The current then splits across connection 312, flowing through access devices 308 and 310.

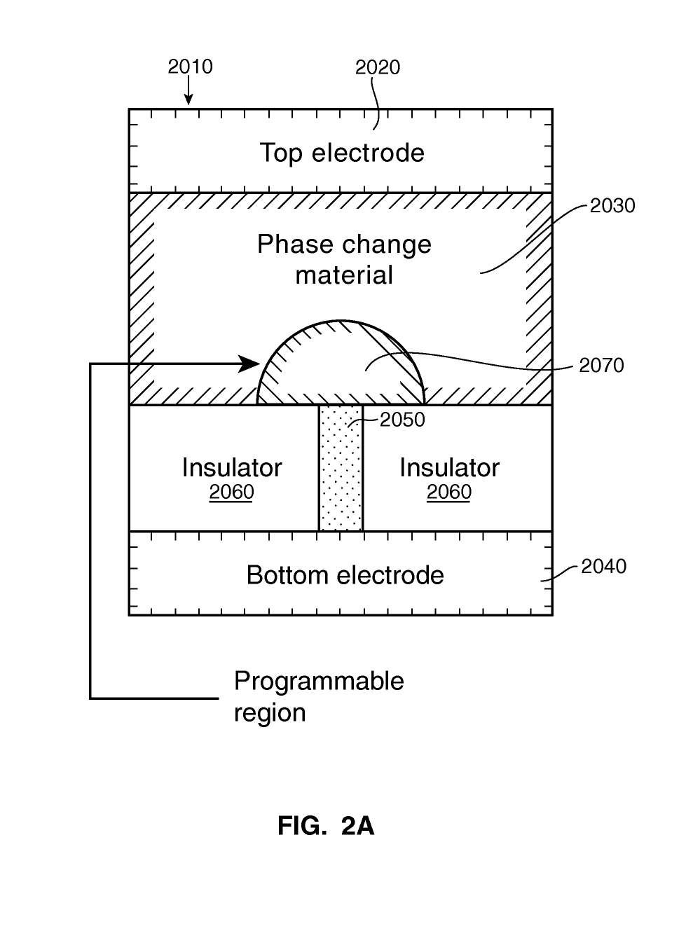

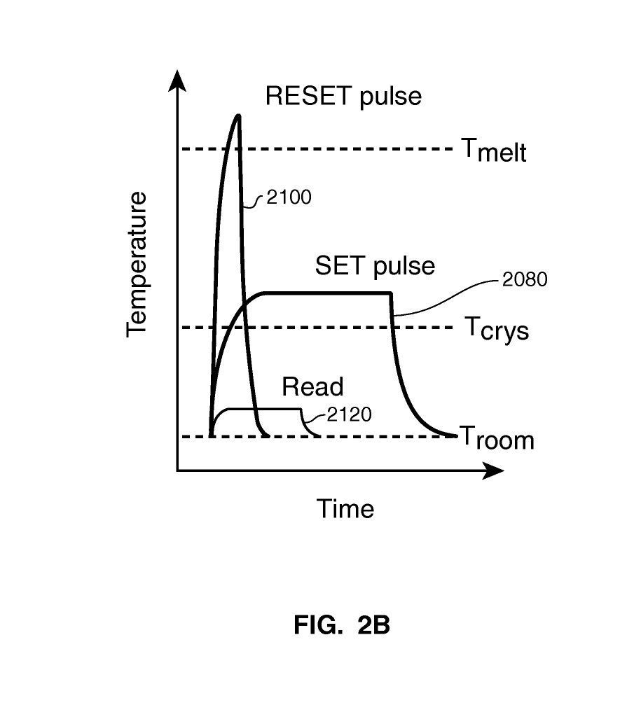

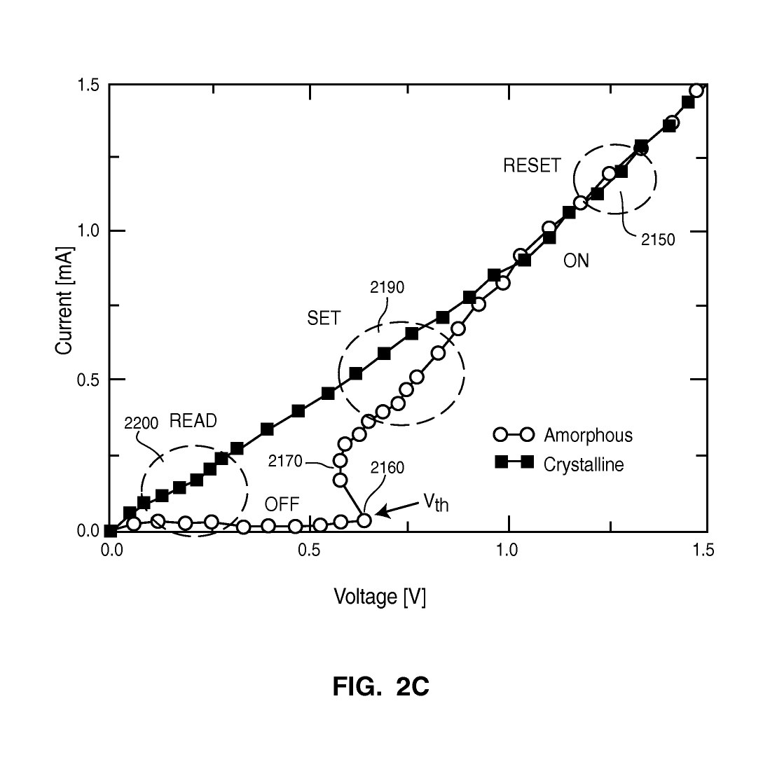

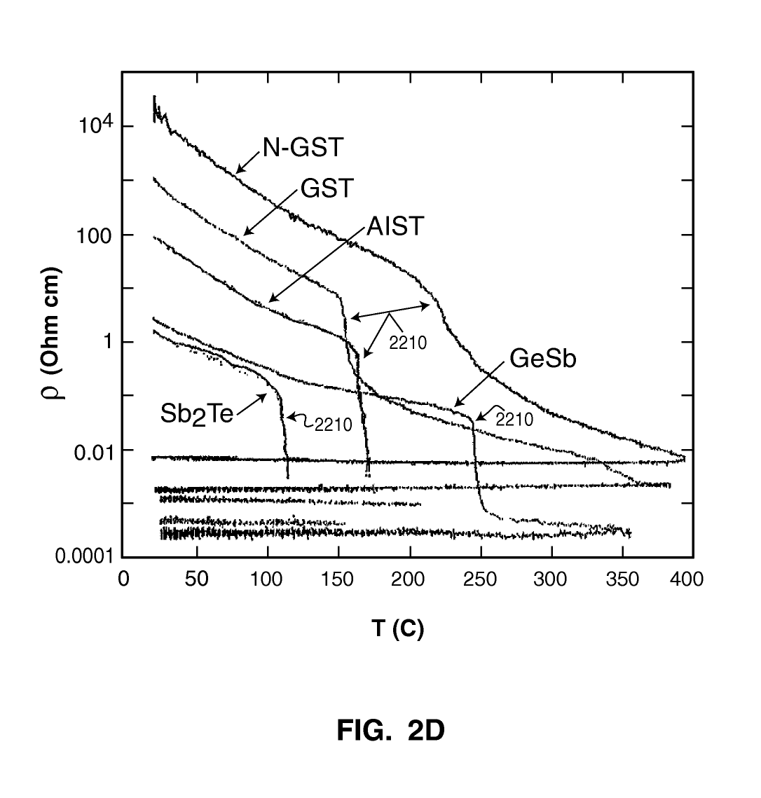

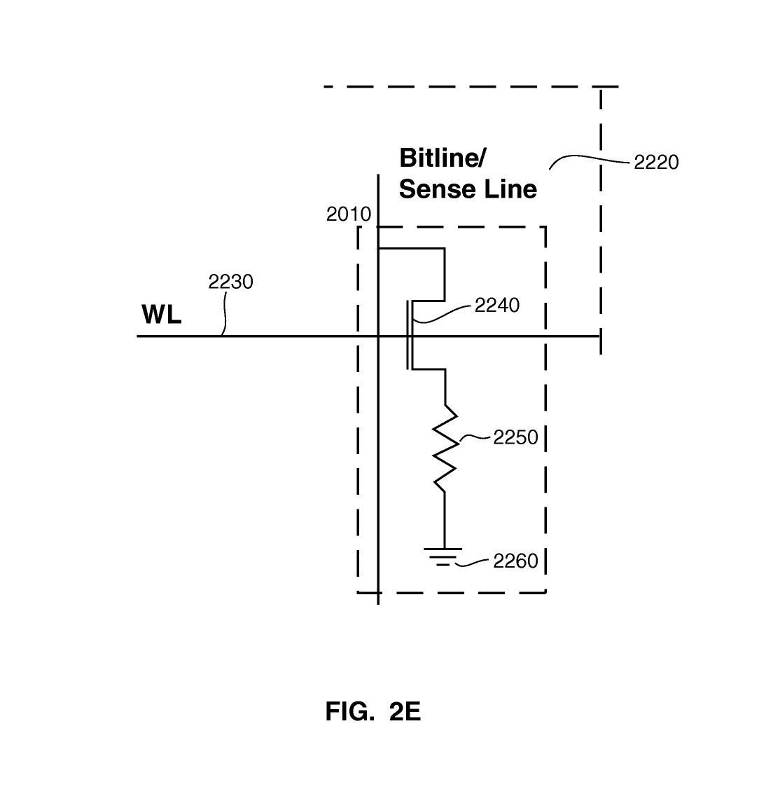

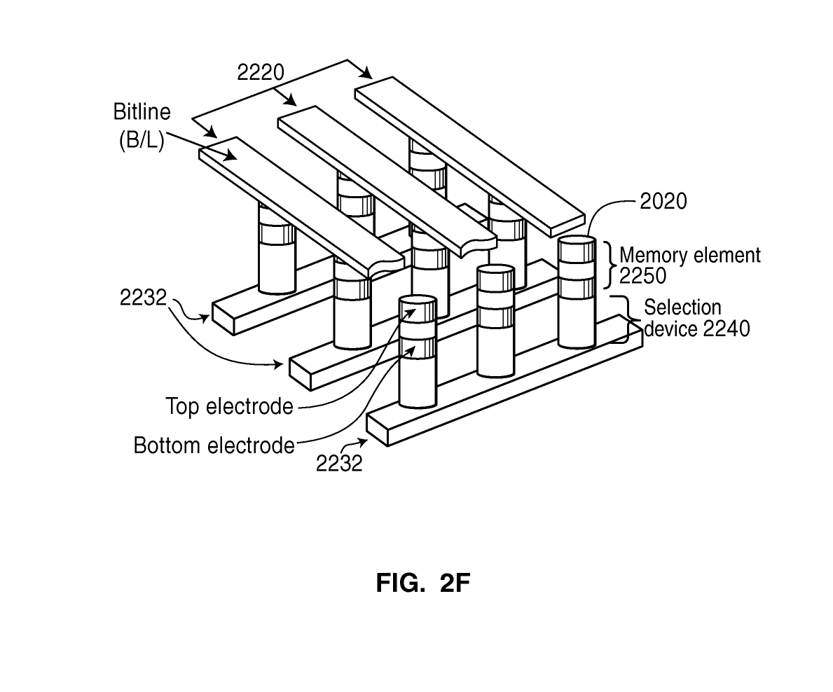

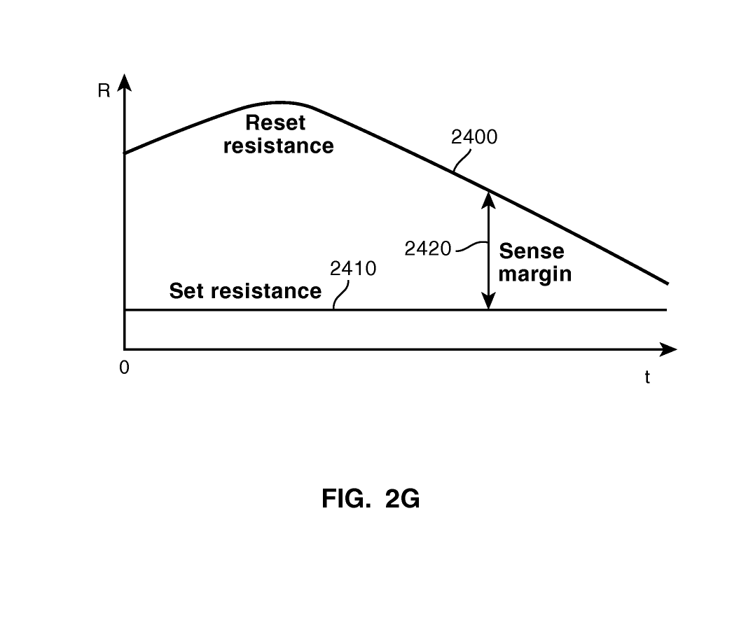

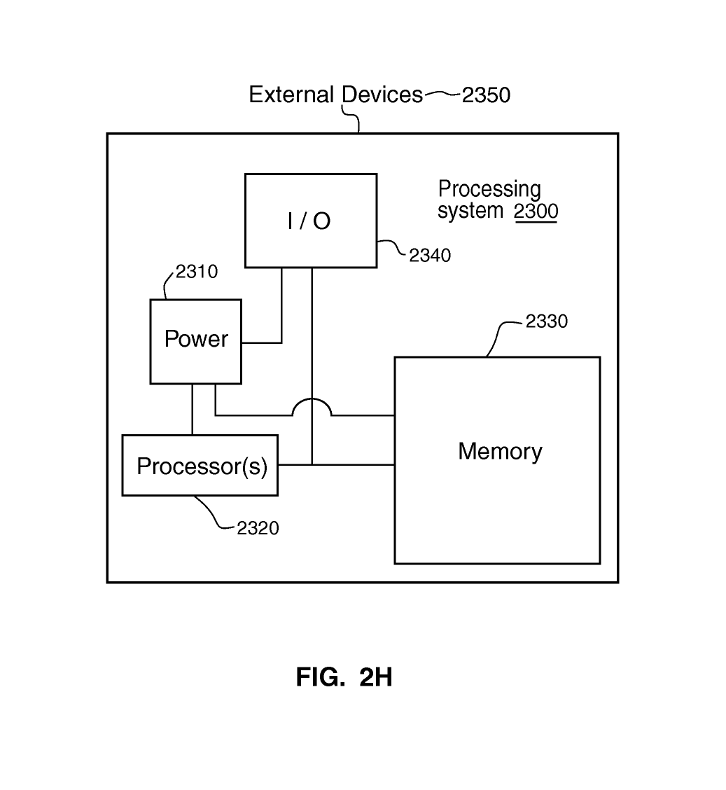

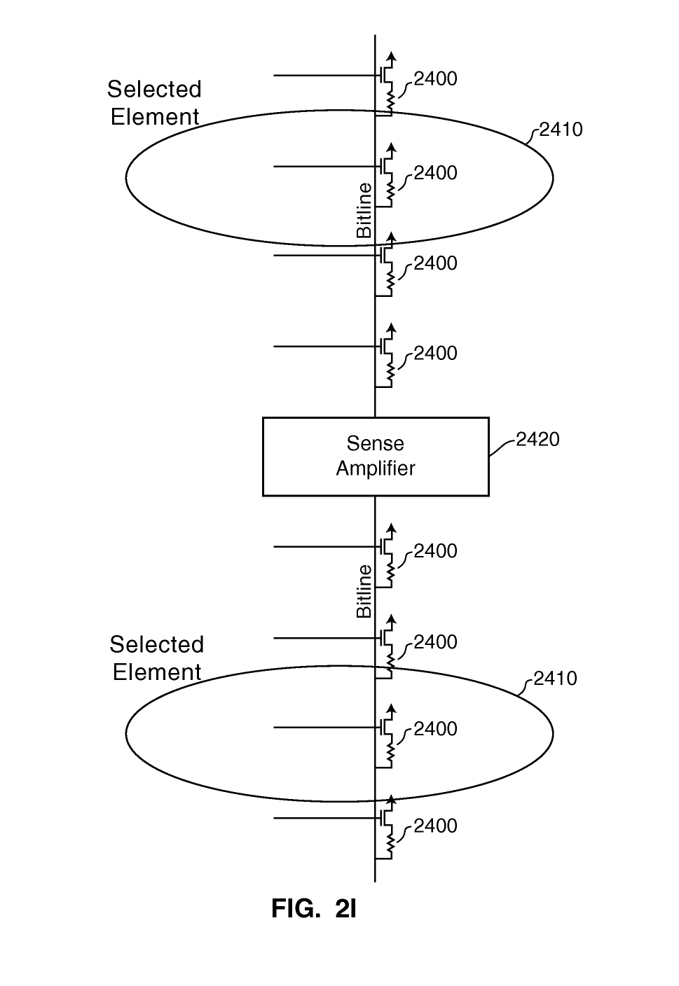

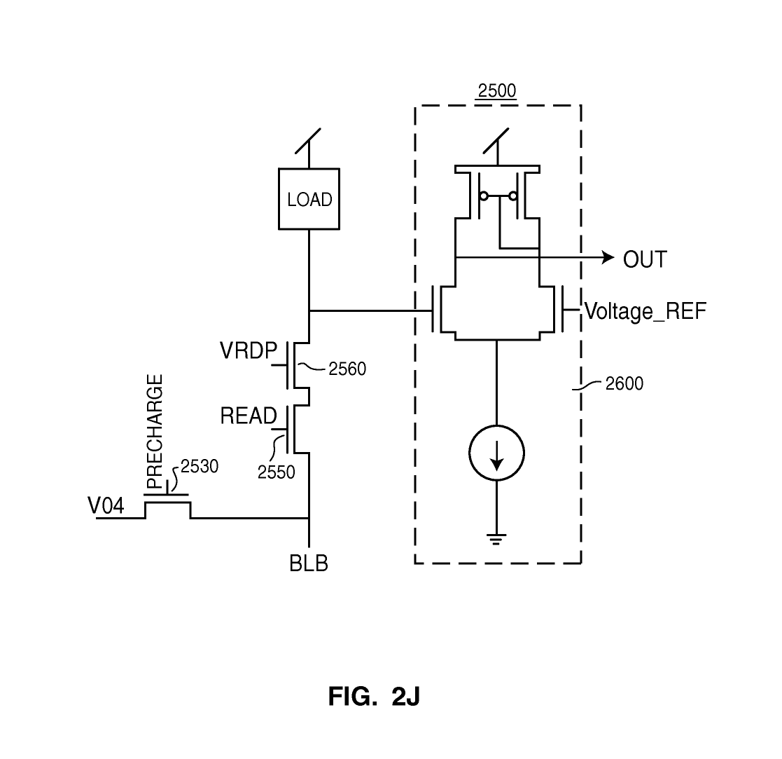

Note that, whereas the PCM element can conventionally be either between the bit line and the access device, as e.g. in FIG. 3, or between the access device and ground, as e.g. in FIG. 2E, the present application teaches that cells using bit line sharing have the PCM element between the bit line and the access device.

When multiple PCM elements are connected as taught herein, preferably only one word line and one bit line from each set of connections can be selected at a time.

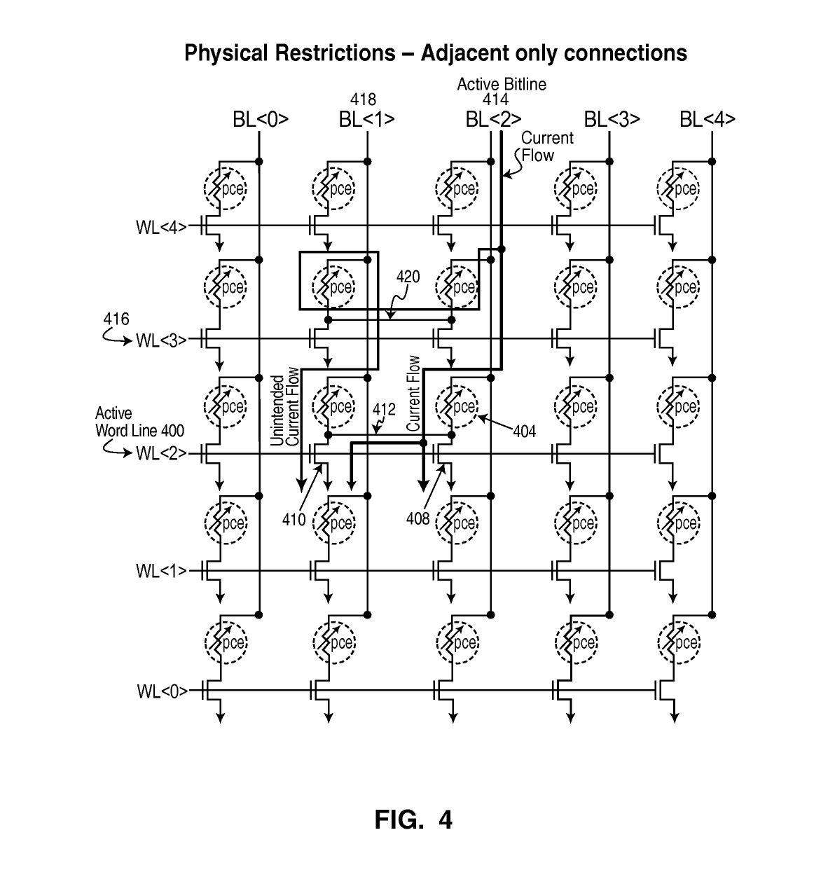

The present application teaches that, in order to prevent current loops and minimize parasitic drain, bit line connections are unique between word lines. Two bit lines are not connected to each other on more than one word line. This can be seen, for example, in FIG. 4, which shows one less-preferred implementation in which two bit lines are connected identically on two different word lines, resulting in undesired current flow through unselected elements.

In FIG. 4, PCM element 404 is selected by selecting word line 400 and bit line 414. Primary current flow (i.e. the portion passing along the desired path) passes down active bit line 414, through PCM element 404, then splits across connection 412 and passes through access devices 408 and 410 to ground. However, a portion of the current splits off at (unselected) word line 416, crosses to unselected bit line 418 by way of duplicative connection 420, and then passes through active access device 410 to ground. This unintentional current path has passed through, and potentially accidentally written, three unintended, unselected phase change memory elements. This can occur even if connections 412 and 420 are not identical, but still contain repeated connections.

One technique to avoid such current loops is simply interpose an open circuit to isolate one of the two phase-change memory regions where the conductive strap is placed. This can be easily done by (for example) deleting a contact from the mask set. This produces a hybrid array of full rows mixed with rows (or columns) where half the memory elements have been deleted.

Another way to avoid these current loops is described below, in connection with FIG. 12 and the following figures.

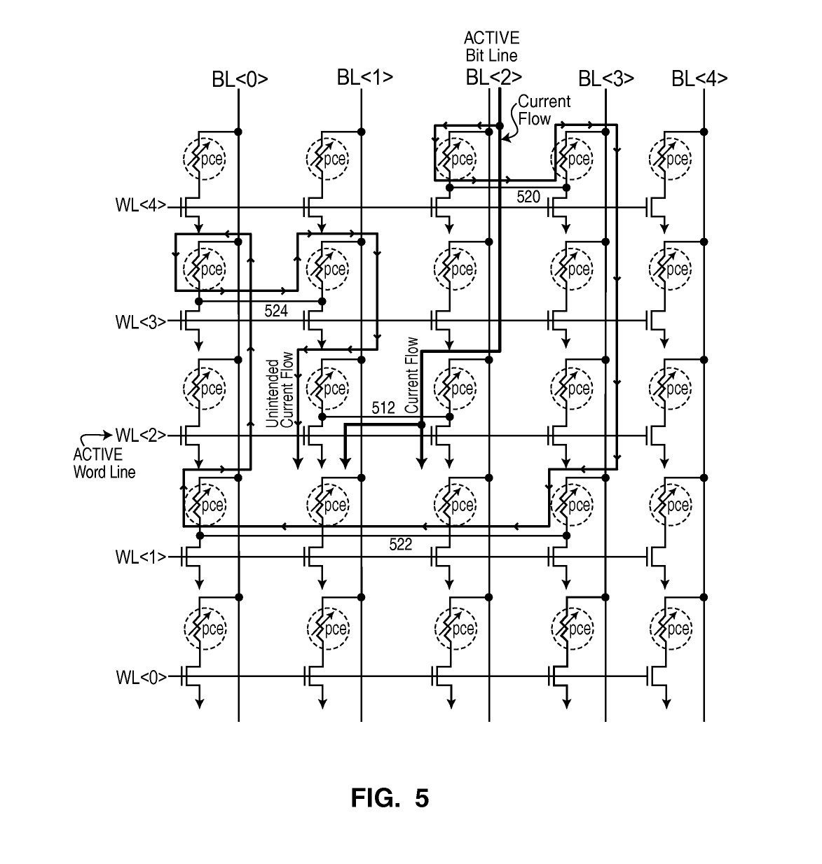

Furthermore, two bit lines cannot be indirectly connected together in more than one unique way. FIG. 5 shows another presently less-preferred implementation, in which the connections can be followed in a loop. Here, while no bit lines are identically connected on different word lines, connections 512, 520, 522, and 524 still form a loop of sorts across word lines, resulting in the unintended current flow shown.

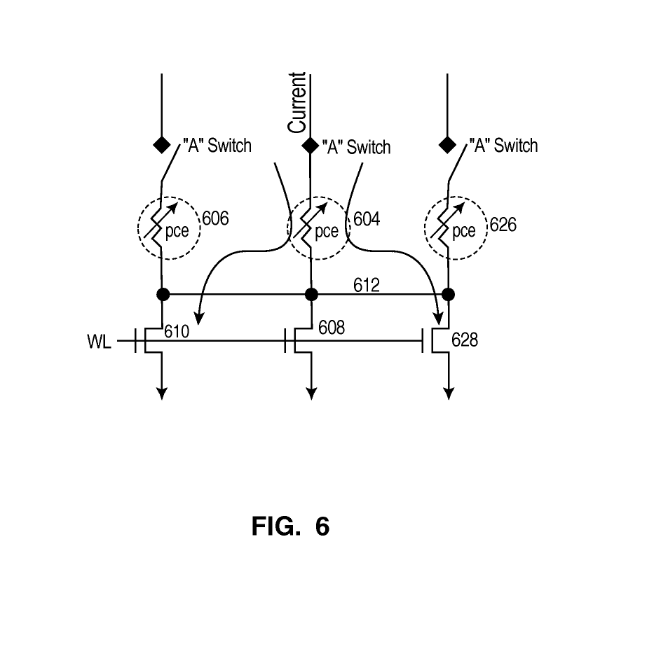

FIG. 6 shows one sample embodiment similar to that of FIG. 3, in which three phase change memory elements 604, 606, and 626 are connected in parallel by connection 612 to access devices 608, 610, and 628.

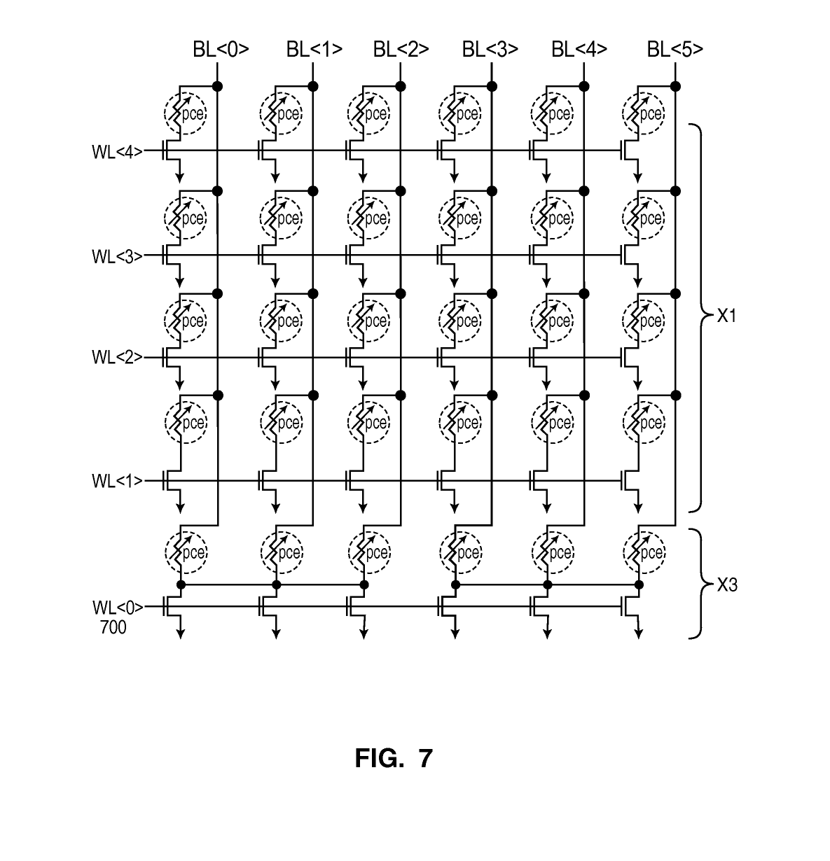

FIG. 7 shows one sample embodiment of a hybrid phase change memory array in which groups of three phase change elements are connected together in parallel. When only adjacent connections are permitted and loops are excluded, only one word line 700 can share groups of three in parallel as shown.

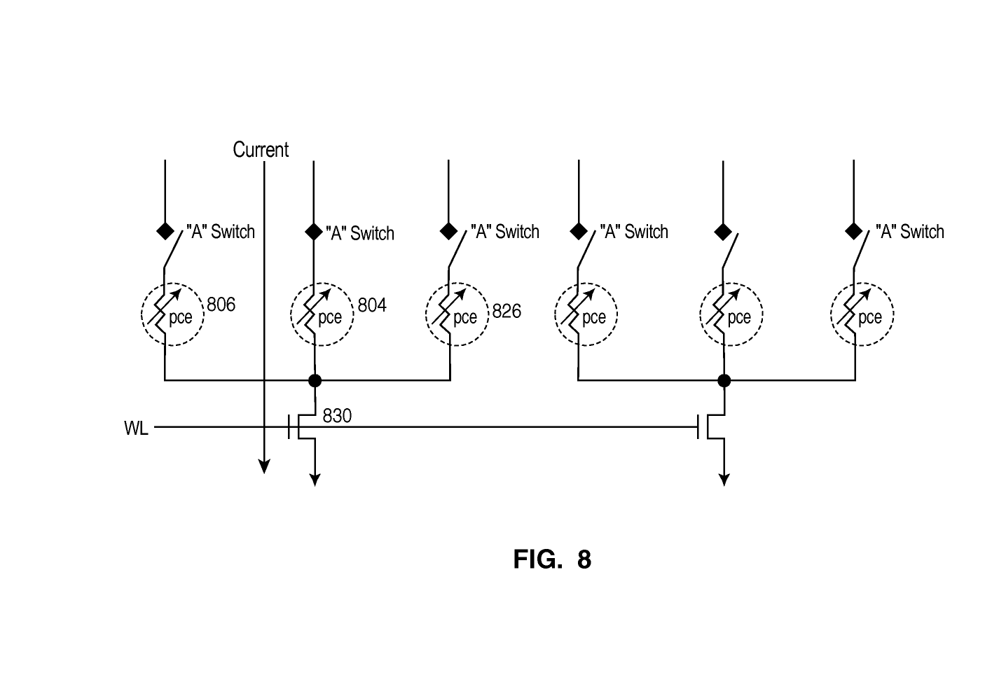

FIG. 8 shows a sample embodiment in which multiple phase change memory elements share a single larger access device in parallel. Phase change memory elements 804, 806, and 826 share access device 830. In this case, while each shared access device is larger than an unshared access device, fewer shared access devices are required.

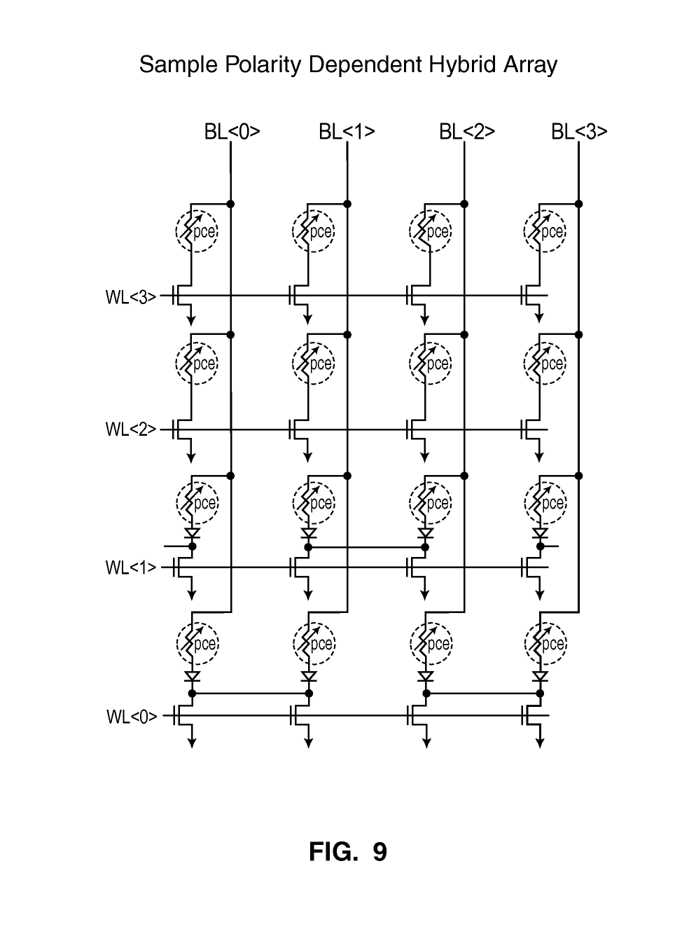

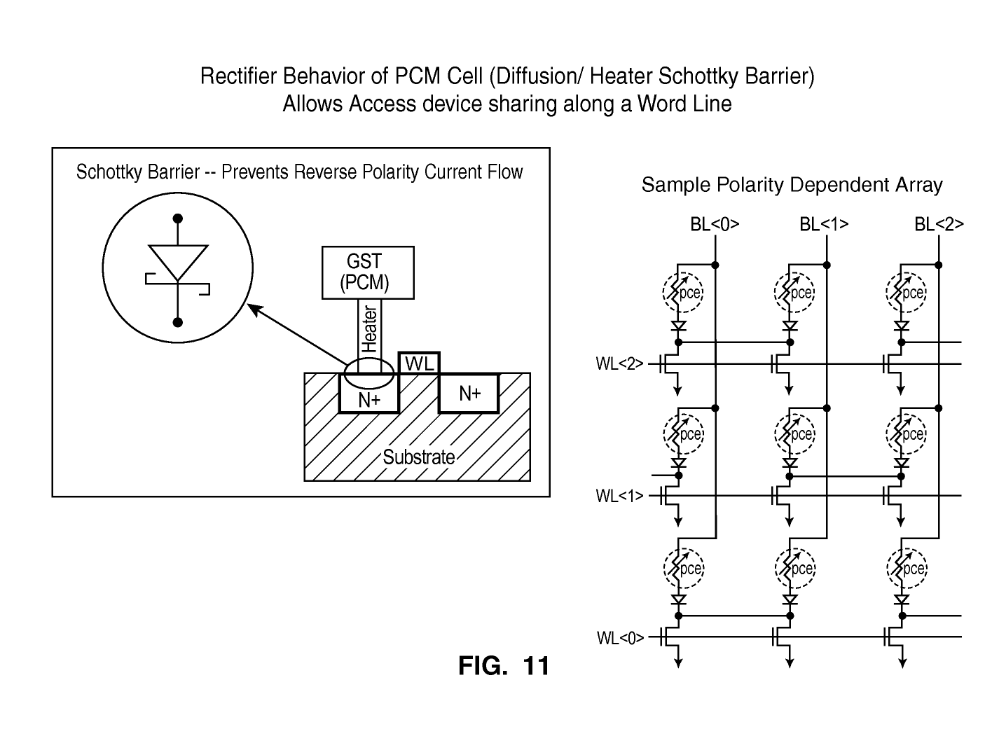

FIG. 9 shows a different hybrid. Note that in this example diodes are shown only on the rows of the array which have the localized strapping, and not on the other rows. This can be achieved by using selective Schottky barrier contacts, as shown in FIG. 11.

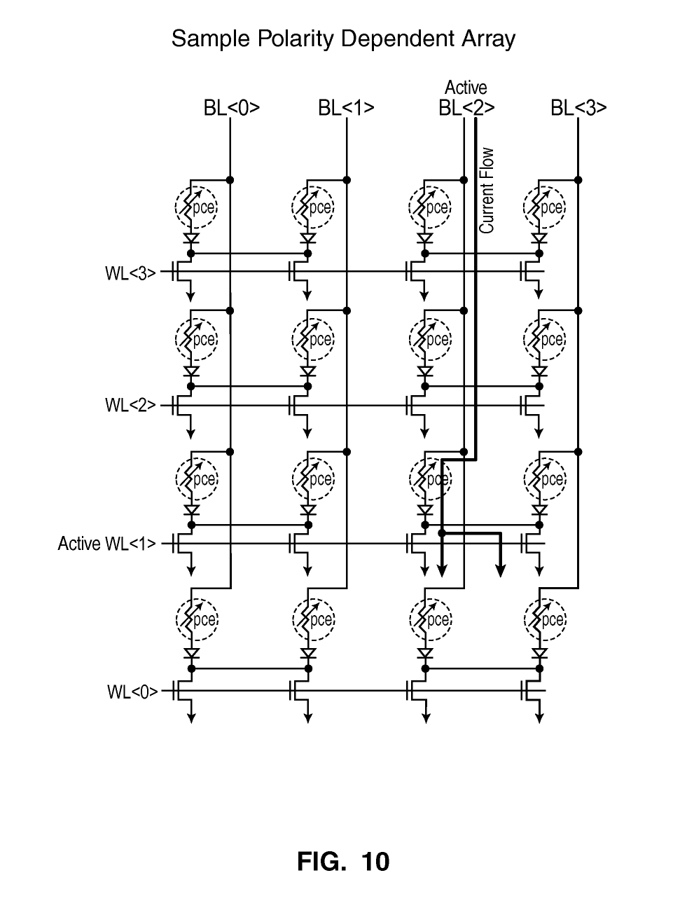

FIG. 10 shows a current path through a sample polarity dependent hybrid array such as that of FIG. 9. The diodes prevent any of the current loops which are shown in FIG. 4.

FIG. 11 shows a sample embodiment of a polarity dependent hybrid array. By patterning the n+ diffusion of the access transistor, or by adding or blocking a contact barrier layer under the metal pillars, this embodiment proposes to provide Schottky barrier diodes in some locations.

In one sample embodiment, the word line voltage can be e.g. 2.5 V for READ, SET, and RESET operations, and the bit line voltage can be e.g. 2.5 V for SET operations, e.g. 3.0 V for RESET operations and e.g. 400 mV for READ operations.

In some sample embodiments, connections are made only between adjacent elements. The additional space required for connecting together non-adjacent elements can diminish or even negate the space saved by the teachings of the present application.

In some sample embodiments wherein connections are made only between adjacent elements, the number of word lines which can have connected elements without repeated connections is limited.

In some sample embodiments, word lines having shared bit lines can be limited to a few word lines at the edges of the PCM array. This can be used advantageously when only adjacent bit lines are connected.

In some sample embodiments which permit non-adjacent bit lines to be connected, the number of word lines which can have connected bit lines can be increased.

In some sample embodiments, every word line can have at least one set of connected elements.

A FET that is operating in the saturation region has a current that will be strongly dependent on its gate (word line) voltage V_{GS} and weakly dependent on its drain (bit line) voltage V_{DS}. If the gate is overdriven, more current can be passed, as is conventionally done to pass RESET current. To optimize the current both the word line and the bit line voltages are preferably large. Bit line voltage (V_{DS}) does have to remain greater than V_{GS}−Vₜₕ (i.e. word line voltage minus threshold voltage). If bit line voltage V_{DS} is the same as word line voltage V_{GS}, this condition is assured.

In some sample embodiments, several PCM elements share a single larger access device. In such a configuration, while each individual access device is larger than conventional, the number of access devices can be reduced. This can permit the use of access devices having larger geometries without negatively impacting cell density.

According to some but not necessarily all embodiments, there is provided: A method of operating a phase change memory, comprising: during a reset operation, selecting a wordline on which at least some phase-change memory cells have localized connections to adjacent coupled cells, and activating a drive transistor which is shared by a plurality of said adjacent coupled cells, while activating only one bitline which is connected to said plurality of adjacent coupled cells, to thereby pull maximal current through the phase-change material of only one said of said adjacent coupled memory cells which is connected to said bit line, but not through the respective resistors of phase change memory cells which are connected to other ones of said bit lines.

According to some but not necessarily all embodiments, there is provided: An array of phase change memory cells, each comprising a phase-changing material and an access transistor, comprising: in at least a first row of said array, a plurality of said cells which share a localized connections at a node between said phase-changing material and said access transistor; and wherein the majority of said cells in said array do not have said connections.

According to some but not necessarily all embodiments, there is provided: A method of operating a phase change memory array, comprising: when a reset operation is desired for one or more cells in a first row of said array, activating both a drive transistor for the respective bit line which is connected to said cell, and another drive transistor which is connected to an adjacent bit line of said array, while said adjacent bit line is floated and said respective bit line is driven, cells in said first row being connected together in pairs by localized cell-to-cell connections; and when cells in other rows of said array are written, then activating only a respective one of said drive transistors which is connected thereto.

According to some but not necessarily all embodiments, there is provided: A method of operating a phase change memory array, comprising: when a reset operation is desired for at least one cell in a first row of said array, activating a first pull-down transistor for a first bit line which is connected to said cell, and also activating a second pull-down transistor which is connected to a second bitline of said array, while activating a first pull-up transistor to pull up said first bitline, and not activating a second pull-up transistor which is connected to said second bit line; wherein said cells in said first row are connected together in pairs by localized cell-to-cell connections; and when cells in other rows of said array are to be reset, then activating only one of said pull-down transistors and only one of said pull-up transistors per cell.

According to some but not necessarily all embodiments, there is provided: A method of operating a phase change memory array, comprising:

when a reset operation is desired for one or more cells in a row of said array, activating both a drive transistor for the respective bit line which is connected to said cell, and another drive transistor which is connected to an adjacent bit line of said array, while said adjacent bit line is floated and said respective bit line is driven, cells in said row being connected together in pairs by localized cell-to-cell connections.

According to some but not necessarily all embodiments, there is provided: A phase change memory, comprising: a plurality of phase change memory elements, each connected to a bit line and also to a respective access device; wherein each said access device is controlled by a word line; and wherein each said access device will only conduct current when the respective word line is selected; wherein two or more said phase change memory elements share a single common access device; and wherein two of said phase change memory elements which share a single common access device will not be selected simultaneously.

According to some but not necessarily all embodiments, there is provided: A method of fabricating a phase change memory, comprising: providing a plurality of phase change memory elements; arranging said phase change memory elements in an array; connecting each respective phase change memory element in a common column of said array to a common bit line; connecting each said phase change memory element to a respective access device; connecting each respective access device in a common row of said array to a common word line; wherein each access device which is controlled by a word line will only conduct current when said word line is selected; forming one or more connection groups; wherein each said connection group is formed by connecting together two or more access devices controlled by a common word line near the respective phase change memory elements.

According to some but not necessarily all embodiments, there is provided: Methods and systems for phase change memory having high RESET currents. In some sample embodiments, PCM elements share access devices in parallel between bit lines, permitting higher RESET currents to be shared between several access devices without overdriving. Lower individual current densities permit smaller access devices and smaller memories having greater reliability and longer retention. In some sample embodiments, hybrid arrays connect bit lines on only a few word lines, using the shared bits e.g. only for critical information. In some sample embodiments, several PCM elements share a single larger access device which can pass higher currents while still reducing the total memory size.

According to some but not necessarily all embodiments, there is provided: A phase change memory system, comprising: a first and a second phase change memory element, each connected both to a respective bit line and also to a respective access device; wherein said access devices are identically electrically connected to a single common word line; and wherein each said access device only conducts current when said word line is selected; wherein the ends of the respective access devices nearest the respective phase change memory element are electrically connected together; wherein the respective bit lines of said first and second PCM elements are never selected simultaneously.

According to some but not necessarily all embodiments, there is provided: A PCM memory system, comprising: a plurality of bit lines; a plurality of word lines; wherein each said bit line connects to a plurality of PCM elements; and wherein each said PCM element connects to a respective access device which is controlled by one said word line; wherein each access device controlled by a word line can conduct current only when said word line is selected; wherein at least two access devices which are controlled by a common word line are electrically connected together at the ends nearest the respective PCM element; wherein no two bit lines share more than one such connection; wherein bit lines which are connected to a selected bit line will not be selected; and wherein said connections are present on only some of said word lines.

According to some but not necessarily all embodiments, there is provided: A phase change memory system, comprising: a first and a second phase change memory element, each connected to a respective bit line and also to a respective access device; wherein said access devices are identically controlled by a single common word line; and wherein each said access device only conducts current when said word line is selected; wherein the ends of the respective access devices near the respective phase change memory elements are electrically connected together; wherein the respective bit lines of said first and second phase change memory elements are never selected simultaneously.

According to some but not necessarily all embodiments, there is provided: A phase change memory system, comprising: a plurality of bit lines; a plurality of word lines; wherein each said bit line connects to a plurality of PCM elements, and each said respective PCM element connects to a respective access device which is controlled by one said word line; wherein each access device controlled by a word line can conduct current only when said word line is selected; wherein at least two access devices which are controlled by a common word line are electrically connected together near the respective PCM elements; wherein no two bit lines share more than one such connection; wherein bit lines which are connected to a selected bit line will not be selected.

### MODIFICATIONS AND VARIATIONS

As will be recognized by those skilled in the art, the innovative concepts described in the present application can be modified and varied over a tremendous range of applications, and accordingly the scope of patented subject matter is not limited by any of the specific exemplary teachings given. It is intended to embrace all such alternatives, modifications and variations that fall within the spirit and broad scope of the appended claims.

In one contemplated embodiment, memory subarrays having bit line sharing are used to store configuration information for accessing subarrays in the main memory array.

While it is presently preferable to minimize or exclude the occurrence of “loops” (such as, e.g., identical connections repeated across word lines), it is contemplated that developments in phase change memories can permit tolerance of loops.

In one contemplated embodiment, a phase-change memory array comprising 2ⁿ+k subarrays has k subarrays with bit line sharing. One of these k subarrays is used to copy one of the 2ⁿ subarrays not sharing bit lines. The k subarray stands in for the 2ⁿ subarray while repeated RESET operations are performed on the 2ⁿ subarray to restore it to a clean, wiped state. Once the 2ⁿ subarray has been restored to a clean state, the previous data is restored to the 2ⁿ subarray from the k subarray, and the k subarray is wiped and used to clean another 2ⁿ subarray in the same way. In this way, the 2ⁿ subarrays can be cleaned in turn to minimize loss and error over time. The decreased time to perform a RESET operation provided by the teachings of the instant application can be particularly useful in this context.

In one contemplated alternative embodiment, current loops through unselected PCM cells can be used in writing multiple PCM cells simultaneously.

In one alternative embodiment in which several PCM elements share a single larger access device, the access device can be located remotely.

An advantage of this design is that it removes a constraint on the cell pitch, and more specifically on the column pitch of the array of PCM cells. The drive current of the pull-down transistor which connects to each bit column is determined by the width of that transistor, so it is possible that a dramatic shrinkage in cell pitch can lead to narrower transistors which have less drive current. If the drive current of any single transistor, because of such reduction in pitch, is not sufficient to reliably reset the cells, then a further option is to include more bit lines connected to a single pull-down transistor. For instance, although FIG. 8 shows exactly three bit lines connected to one pull-down transistor, it also possible to have e.g. four or eight bit lines, etc., in order to ensure that the pull-down transistor has sufficient drive capability under all conditions.

An unintended consequence of having many word lines where the shared access devices repeat for multiple word lines is a connection through an unselected PCM in parallel with the selected PCM. This has the potential to unintentionally write an unselected cell. In one contemplated alternative embodiment, this is used to write a cell with a voltage just higher than the snap back voltage, which can work for a plurality of word lines without writing an unselected cell.

An advantage of this configuration is that the row or two of cells with localized cell connections can achieve higher drive currents, for reliable set and reset, even if the main memory array is worn out. This is particularly advantageous for encoding of redundancy data, or other configuration data, since the rows which have bitline sharing are more robust.

An important advantage of this mode of memory array operations, in embedded memory and in systems, is that no excess power is consumed on refresh operations, or on set or reset operations which are more than needed for the current state of memory. Even phase-change memories have some life cycle, although phase change memory is more advantageous in this respect than other nonvolatile memory technologies. Thus for long-time operation, cell refresh can be desirable, as discussed in other applications. Moreover, in many applications, the energy efficiency can be a driving factor. In this case, it is highly desirable not to exercise the nonvolatile memory more often than is required to assure system sanity. Thus the use of temperature compensation for set and reset operations provides optimal system stability without any excess energy or power consumption.

None of the description in the present application should be read as implying that any particular element, step, or function is an essential element which must be included in the claim scope: THE SCOPE OF PATENTED SUBJECT MATTER IS DEFINED ONLY BY THE ALLOWED CLAIMS. Moreover, none of these claims are intended to invoke paragraph six of 35 USC section 112 unless the exact words “means for” are followed by a participle.

The claims as filed are intended to be as comprehensive as possible, and NO subject matter is intentionally relinquished, dedicated, or abandoned.

1. A method of operating a phase change memory, comprising:
during a reset operation,
selecting a wordline on which at least some phase-change memory cells have localized connections to adjacent coupled cells, and activating a drive transistor which is shared by a plurality of said adjacent coupled cells, while
activating only one bitline which is connected to said plurality of adjacent coupled cells, to thereby pull maximal current through the phase-change material of only one said of said adjacent coupled memory cells which is connected to said bit line, but not through the respective resistors of phase change memory cells which are connected to other ones of said bit lines.

2. An array of phase change memory cells, each comprising a phase-changing material and an access transistor, comprising:
in at least a first row of said array, a plurality of said cells which share a localized connections at a node between said phase-changing material and said access transistor;
and wherein the majority of said cells in said array do not have said connections.

3. A method of operating a phase change memory array, comprising:
when a reset operation is desired for one or more cells in a first row of said array, activating both a drive transistor for the respective bit line which is connected to said cell, and another drive transistor which is connected to an adjacent bit line of said array, while said adjacent bit line is floated and said respective bit line is driven, cells in said first row being connected together in pairs by localized cell-to-cell connections; and
when cells in other rows of said array are written, then activating only a respective one of said drive transistors which is connected thereto.

4.-7. (canceled)
